(19) United States
(12) Patent Application Publication
(10) Pub. No.: US 2007/0056930 A1
(43) Pub. Date: Mar. 15, 2007

(54) POLYSILICON ETCHING METHODS

(75) Inventors: Seiji Iseda, Katonah, NY (US); Siddhartha Panda, Beacon, NY (US); Michael R. Sievers, Poughkeepsie, NY (US); Richard S. Wise, New Windsor, NY (US)

Correspondence Address: HOFFMAN, WARNICK & D'ALESSANDRO LLC, 75 STATE ST, 14TH FL, ALBANY, NY, 12207, US

(73) Assignees: INTERNATIONAL BUSINESS MACHINES CORPORATION, Armonk, NY (US); SONY CORPORATION, Tokyo (JP); SONY ELECTRONICS INC., Park Ridge, NJ (US)

(21) Appl. No.: 11/162,550

(22) Filed: Sep. 14, 2005

(51) Int. Cl. C03C 25/68; B44C 1/22; H01L 21/461; C23F 1/00

(52) U.S. Cl. 216/79; 438/706; 216/58

(57) ABSTRACT

Polysilicon etching methods are disclosed that employ a gas flow including perfluorocyclopentene (C₅F₈) and nitrogen trifluoride (NF₃). The etching methods achieved a substantially vertical profile and smoother surfaces, and may achieve a 3sigma variation as low as 3.0 nm.

### BACKGROUND OF THE INVENTION

1. Technical Field

The invention relates generally to semiconductor device fabrication, and more particularly, to methods for etching polysilicon.

2. Background Art

In the semiconductor device fabrication industry, etching of polysilicon in a uniform and clean manner while achieving the desired dimensions is a continuing challenge. Current polysilicon conductor etching method variation requirements mandate that a total 3sigma variation should be approximately 5 nm. The first step in etching polysilicon in a softmask framework is referred to as cap overetch. Conventional cap overetch chemistries provide a 3sigma variation of approximately 12 nm. Furthermore, as shown in FIG. 1, another shortcoming of conventional cap overetch chemistries is that they inadequately provide a polysilicon profile 10 that is tapered, while a nearly vertical and smooth profile is desired.

Perfluorocyclopentene (C₅F₈) has been used to etch silicon dioxide (SiO₂) and silicon nitride (Si₃N₄) and metallic polymers, and has been used in combination with difluoromethane (CH₂F₂) to etch bulk silicon, but it has never been applied to polysilicon.

In view of the foregoing, there is a need in the art for improved polysilicon etching methods.

### SUMMARY OF THE INVENTION

Polysilicon etching methods are disclosed that employ a gas flow including perfluorocyclopentene (C₅F₈) and nitrogen trifluoride (NF₃). The etching methods achieved a substantially vertical profile and smoother surfaces, and may achieve a 3sigma variation as low as 3.0 nm.

A first aspect of the invention provides a method of etching polysilicon in an etching chamber, the method comprising the steps of: opening a capping layer over a polysilicon layer; and first etching the polysilicon layer using a chemistry including a gas flow including perfluorocyclopentene (C₅F₈) and nitrogen trifluoride (NF₃).

A second aspect of the invention provides a method of etching polysilicon in an etching chamber, the method comprising the steps of: opening a capping layer over a polysilicon layer; first etching the polysilicon layer using a chemistry including a gas flow including perfluorocyclopentene (C₅F₈) and nitrogen trifluoride (NF₃); and second etching to remove any polysilicon remainders.

A third aspect of the invention provides a method of etching polysilicon in an etching chamber, the method comprising the steps of: opening a capping layer over a polysilicon layer; generating a substantially vertical profile in the polysilicon layer by: first etching the polysilicon layer using a chemistry including a gas flow including perfluorocyclopentene (C₅F₈) and nitrogen trifluoride (NF₃); and second etching to remove any polysilicon remainders

The illustrative aspects of the present invention are designed to solve the problems herein described and other problems not discussed, which are discoverable by a skilled artisan.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a polysilicon stack formed according to one conventional etching process.

FIGS. 2-7 show a polysilicon etching method according to one embodiment of the invention.

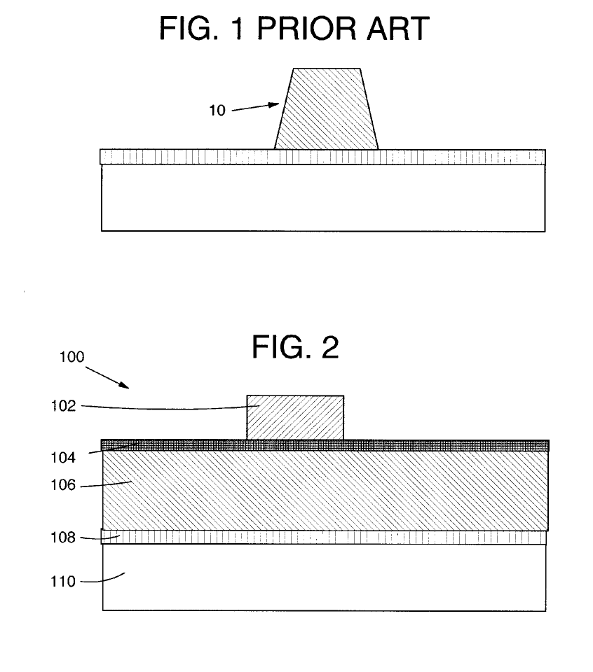

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

Turning to the drawings, FIGS. 2-7 show polysilicon etching methods according to embodiments of the invention. The methods will be described relative to a polysilicon gate. It should be recognized, however, that the methods may be applied to a variety of polysilicon structures.

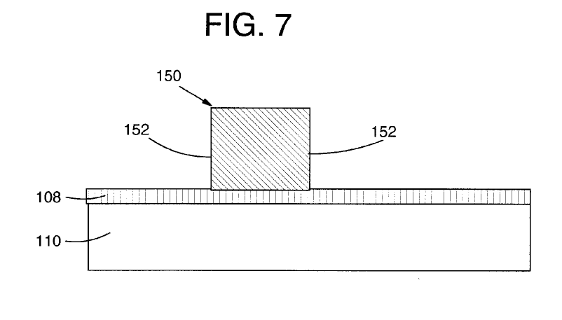

In the illustrative embodiment, as shown in FIG. 2, the methods begin with a structure 100 including a photoresist 102 patterned for forming a polysilicon stack 150 (FIG. 7), a capping layer 104 over a polysilicon layer 106, a silicon dioxide (SiO₂) layer 108 under the polysilicon layer 106 and a silicon wafer 110 under silicon dioxide layer 108. In one embodiment, capping layer 104 may include any now known or later developed anti-reflective coating (ARC). Capping layer 104 may also include any other conventional capping material such as silicon nitride (Si₃N₄), etc. As used herein, “polysilicon layer” 106 may include any form of polycrystalline silicon and may include dopants or other impurities as known in the art. Structure 100 would be placed in a conventional etching chamber (not shown). As one with skill in the art recognizes, such an etching chamber typically includes a top electrode, a bottom electrode, a sources of gas, a main gas flow intake, a lower portion gas flow intake, a radio frequency (RF) energy generator for controlling energy emitted by each electrode and other required control systems.

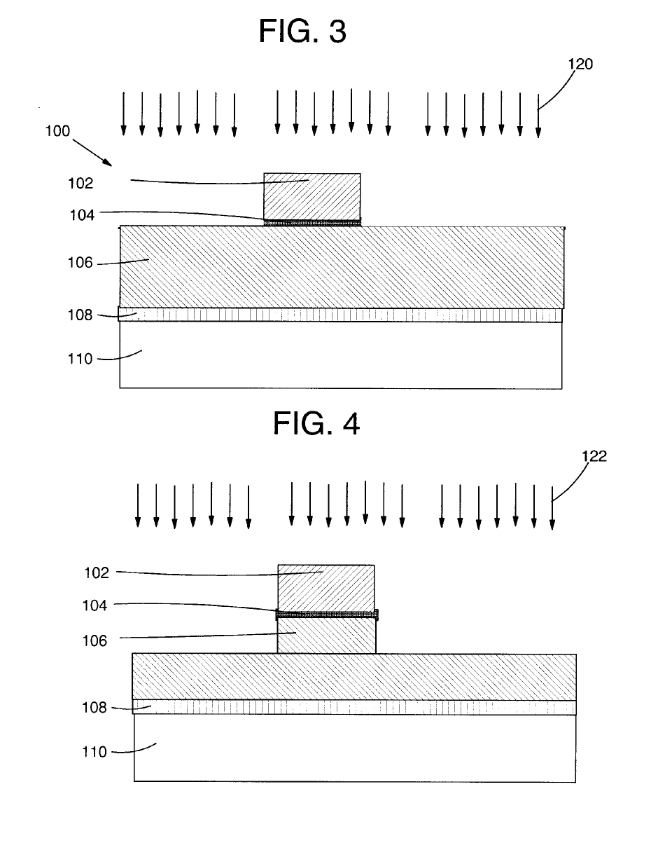

In a first step, shown in FIG. 3, capping layer 104 is opened over polysilicon layer 106. This step may include, for example, etching 120 using approximately 5-20 mTorr pressure and an RF energy of approximately 200-300 Watts plasma power and approximately 50-150 Watts bias power. “Plasma power” indicates the RF energy used to control the plasma (hence species), and “bias power” indicates the RF energy used to control the impinging ion power. In one preferred embodiment, this step includes etching 120 using approximately 8 mTorr pressure and an RF energy of approximately 250 Watts plasma power and approximately 75 Watts bias power. In addition, a gas flow for the etching may include, in one embodiment, approximately 40-70 standard cubic centimeters (sccm) tetrafluoromethane (CF₄), approximately 10-20 sccm oxygen (O₂) and approximately 5-15 sccm difluoromethane (CH₂F₂). In one preferred embodiment, the gas flow for the etching includes: approximately 55 standard cubic centimeters (sccm) tetrafluoromethane (CF₄), approximately 12 sccm oxygen (O₂) and approximately 7.5 sccm difluoromethane (CH₂F₂).

FIG. 4 shows a next step includes etching 122 polysilicon layer 106 using a chemistry including a gas flow including perfluorocyclopentene (C₅F₈) and nitrogen trifluoride (NF₃). In contrast to the conventional methods, the use of perfluorocyclopentene (C₅F₈) and nitrogen trifluoride (NF₃) has been found to achieve a substantially vertical profile, e.g., no more than 10-15 nm difference between a top width and bottom width, for the polysilicon stack 150 (FIG. 7). Surfaces 152 (FIG. 7) of polysilicon stack 150 are also smoother than those formed by conventional methods as a result of the use of the perfluorocyclopentene (C₅F₈) and nitrogen trifluoride (NF₃). In addition, a 3sigma variation capability achievable may be as low as 3.0 nm, which is a vast improvement over current methods. In one embodiment, the perfluorocyclopentene (C₅F₈) and nitrogen trifluoride (NF₃) are supplied in a ratio of approximately 1:4. In one particular embodiment, the gas flow includes approximately 5-10 standard cubic centimeters (sccm) perfluorocyclopentene (C₅F₈) and approximately 20-40 sccm nitrogen trifluoride (NF₃). In this case, the etching 122 may include, for example, approximately 5-30 mTorr pressure and an RF energy of approximately 700-1000 Watts plasma power and approximately 100-250 Watts bias power. Where an approximation is provided herein for a range, the approximation is applicable to the lower and upper value. In one preferred embodiment, the gas flow includes approximately 8 standard cubic centimeters (sccm) perfluorocyclopentene (C₅F₈) and approximately 32 sccm nitrogen trifluoride (NF₃). Here, the etching 122 may include, for example, approximately 10 mTorr pressure and an RF energy of approximately 800 Watts plasma power and approximately 200 Watts bias power. Etching 122 may last for approximately 60 seconds.

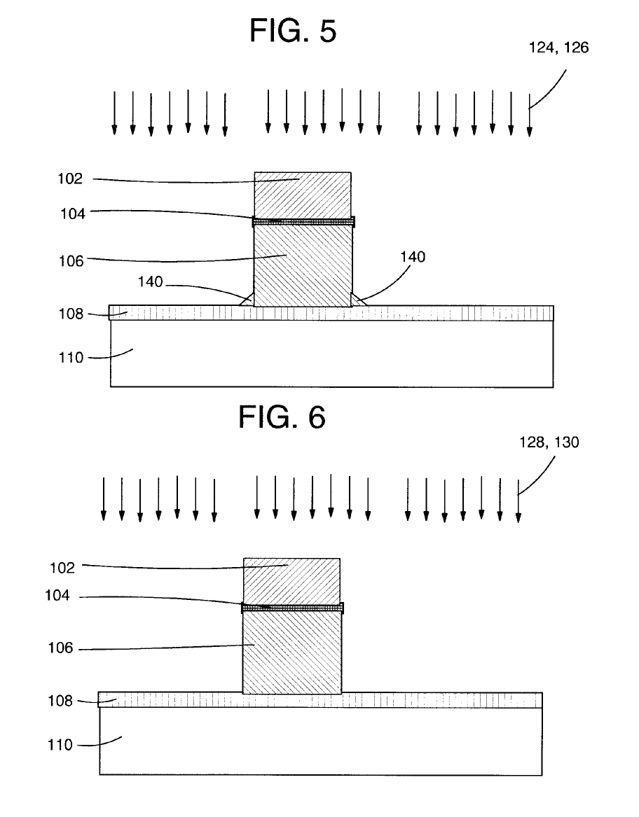

1 Turning to FIG. 5, another etching step (main etch) may be provided to remove polysilicon layer 106 closer to silicon dioxide layer 108. This etching step is selective through polysilicon to silicon dioxide (SiO₂) layer 108 and will not etch layer 108. In one embodiment, this etching step may include more than one stage, perhaps at least two stages. For example, two stages may include a first stage 124 using approximately 15-30 mT of pressure, an RF energy of approximately 150-300 Watts plasma power and approximately 75-200 Watts bias power, and a gas flow including approximately 400-600 standard cubic centimeters (sccm) hydrogen bromide (HBr) and approximately 1-5 sccm oxygen (O₂). In one preferred embodiment of the first stage, approximately 20 mT of pressure, an RF energy of approximately 200 Watts plasma power and approximately 100 Watts bias power, and a gas flow including approximately 450 standard cubic centimeters (sccm) hydrogen bromide (HBr) and approximately 1.5 sccm oxygen (O₂), may be used. A second stage 126 may include using approximately 30-60 mT of pressure, an RF energy of approximately 100-200 Watts plasma power and approximately 100-200 Watts bias power, and a gas flow including approximately 400-600 standard cubic centimeters (sccm) hydrogen bromide (HBr), approximately 1-8 sccm oxygen (O₂) and approximately 400-600 sccm of helium (He). In one preferred embodiment of the second stage approximately 40 mT of pressure, an RF energy of approximately 135 Watts plasma power and approximately 67 Watts bias power, and a gas flow including approximately 500 standard cubic centimeters (sccm) hydrogen bromide (HBr), approximately 5 sccm oxygen (O₂) and approximately 440 sccm of helium (He), may be used. Other etching steps to remove polysilicon remainders 140 may also be used. Each stage 124, 126 may extend for, for example, approximately 55 seconds.

Turning to FIG. 6, another etching step (overetch) may be provided to remove any polysilicon remainders 140 (FIG. 5), e.g., at a footing of a polysilicon stack 150 (FIG. 7). This etching step is even more selective to (gate) silicon dioxide (SiO₂) layer 108 than etching stages 124, 126. This etching step may also include more than one stage. In one embodiment, this etching step includes at least two stages. A first stage 128 may include using approximately 30-60 mT of pressure, an RF energy of approximately 100-200 Watts plasma power and approximately 50-120 Watts bias power, and a gas flow including approximately 400-600 standard cubic centimeters (sccm) hydrogen bromide (HBr), approximately 1-8 sccm oxygen (O₂) and approximately 400-600 sccm of helium (He). In one preferred embodiment of the first stage 128, approximately 40 mT of pressure, an RF energy of approximately 135 Watts plasma power and approximately 100 Watts bias power, and a gas flow including approximately 500 standard cubic centimeters (sccm) hydrogen bromide (HBr), approximately 1.5 sccm oxygen (O₂) and approximately 440 sccm of helium (He), may be used. A second stage 130 may include using approximately 10-40 mT of pressure, an RF energy of approximately 0 Watts plasma power and approximately 100-200 Watts bias power, and a gas flow including approximately 400-600 standard cubic centimeters (sccm) hydrogen bromide (HBr) and approximately 1-8 sccm oxygen (O₂). In one preferred embodiment of second stage 130, approximately 20 mT of pressure, an RF energy of approximately 0 Watts plasma power and approximately 150 Watts bias power, and a gas flow including approximately 50 standard cubic centimeters (sccm) hydrogen bromide (HBr) and approximately 8 sccm oxygen (O₂), may be used. Each stage 128, 130 may last for approximately 55 seconds.

In each of the above-described etching steps a gas flow to a lower portion of the etching chamber may be provided that includes helium (He).

FIG. 7 illustrates a polysilicon stack 150 formed according to the above-described embodiments. The use of perfluorocyclopentene (C₅F₈) and nitrogen trifluoride (NF₃) has been found to achieve a substantially vertical profile for the polysilicon stack 150. In addition, surfaces 152 are typically smoother than those formed by conventional methods. In addition, a 3sigma variation capability achievable may be as low as 3.0 nm, which is a vast improvement over current methods. It should be recognized that the above-described etching parameters are for a 65 nm technology, and that the process may be varied to accommodate different technologies.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method of etching polysilicon in an etching chamber, the method comprising the steps of:
opening a capping layer over a polysilicon layer; and
first etching the polysilicon layer using a chemistry including a gas flow including perfluorocyclopentene (C₅F₈) and nitrogen trifluoride (NF₃).

2. The method of claim 1, wherein the capping layer includes an anti-reflective coating (ARC).

3. The method of claim 1, wherein the opening step includes etching using approximately 5-20 mTorr pressure, an RF energy of approximately 200-300 Watts plasma power and approximately 50-150 Watts bias power, and the gas flow includes approximately 40-70 standard cubic centimeters (sccm) tetrafluoromethane (CF₄), approximately 10-20 sccm oxygen (O₂) and approximately 5-15 sccm difluoromethane (CH₂F₂).

4. The method of claim 1, wherein the first etching step includes using the perfluorocyclopentene (C₅F₈) and nitrogen trifluoride (NF₃) in a ratio of approximately 1:4.

5. The method of claim 1, wherein the first etching step includes using approximately 5-30 mTorr pressure, an RF energy of approximately 700-1000 Watts plasma power and approximately 100-250 Watts bias power, and the gas flow includes approximately 5-10 standard cubic centimeters (sccm) perfluorocyclopentene (C₅F₈) and approximately 20-40 sccm nitrogen trifluoride (NF₃).

6. The method of claim 1, wherein the first etching step lasts for approximately 60 seconds.

7. The method of claim 1, further comprising a second etching step including at least two stages including:
a first stage using approximately 15-30 mT of pressure, an RF energy of approximately 150-300 Watts plasma power and approximately 75-200 Watts bias power, and a gas flow including approximately 400-600 standard cubic centimeters (sccm) hydrogen bromide (HBr) and approximately 1-5 sccm oxygen (O₂); and
a second stage using approximately 30-60 mT of pressure, an RF energy of approximately 100-200 Watts plasma power and approximately 100-200 Watts bias power, and a gas flow including approximately 400-600 standard cubic centimeters (sccm) hydrogen bromide (HBr), approximately 1-8 sccm oxygen (O₂) and approximately 400-600 sccm of helium (He).

8. The method of claim 7, wherein each stage of the second etching extends for approximately 55 seconds.

9. The method of claim 6, further comprising a third etching including at least two stages including:
a first stage using approximately 30-60 mT of pressure, an RF energy of approximately 100-200 Watts plasma power and approximately 50-120 Watts bias power, and a gas flow including approximately 400-600 standard cubic centimeters (sccm) hydrogen bromide (HBr), approximately 1-8 sccm oxygen (O₂) and approximately 400-600 sccm of helium (He); and
a second stage using approximately 10-40 mT of pressure, an RF energy of approximately 0 Watts plasma power and approximately 100-200 Watts bias power, and a gas flow including approximately 400-600 standard cubic centimeters (sccm) hydrogen bromide (HBr) and approximately 1-8 sccm oxygen (O₂).

10. The method of claim 9, wherein each stage of the second and third etching steps lasts for approximately 55 seconds.

11. The method of claim 9, wherein each etching step includes providing a gas flow to a lower portion of the etching chamber including helium (He).

12. The method of claim 1, wherein after the first etching step the polysilicon layer has a substantially vertical profile.

13. A method of etching polysilicon in an etching chamber, the method comprising the steps of:
opening a capping layer over a polysilicon layer;
first etching the polysilicon layer using a chemistry including a gas flow including perfluorocyclopentene (C₅F₈) and nitrogen trifluoride (NF₃); and
second etching to remove any polysilicon remainders.

14. The method of claim 13, wherein the opening step includes etching using approximately 8 mTorr pressure, an RF energy of approximately 250 Watts plasma power and approximately 75 Watts bias power, and the gas flow includes approximately 55 standard cubic centimeters (sccm) tetrafluoromethane (CF₄), approximately 12 sccm oxygen (O₂) and approximately 7.5 sccm difluoromethane (CH₂F₂).

15. The method of claim 13, wherein the first etching step includes using the perfluorocyclopentene (C₅F₈) and nitrogen trifluoride (NF₃) in a ratio of approximately 1:4.

16. The method of claim 13, wherein the first etching step includes using approximately 10 mTorr pressure, an RF energy of approximately 800 Watts plasma power and approximately 200 Watts bias power, and the gas flow includes approximately 8 standard cubic centimeters (sccm) perfluorocyclopentene (C₅F₈) and approximately 32 sccm nitrogen trifluoride (NF₃).

17. The method of claim 13, wherein the second etching step includes at least four stages including:
a first stage using approximately 15-30 mT of pressure, an RF energy of approximately 150-300 Watts plasma power and approximately 75-200 Watts bias power, and a gas flow including approximately 400-600 standard cubic centimeters (sccm) hydrogen bromide (HBr) and approximately 1-5 sccm oxygen (O₂);
a second stage using approximately 30-60 mT of pressure, an RF energy of approximately 100-200 Watts plasma power and approximately 100-200 Watts bias power, and a gas flow including approximately 400-600 standard cubic centimeters (sccm) hydrogen bromide (HBr), approximately 1-8 sccm oxygen (O₂) and approximately 400-600 sccm of helium (He);
a third stage using approximately 30-60 mT of pressure, an RF energy of approximately 100-200 Watts plasma power and approximately 50-120 Watts bias power, and a gas flow including approximately 400-600 standard cubic centimeters (sccm) hydrogen bromide (HBr), approximately 1-8 sccm oxygen (O₂) and approximately 400-600 sccm of helium (He); and
a fourth stage using approximately 10-40 mT of pressure, an RF energy of approximately 0 Watts plasma power and approximately 100-200 Watts bias power, and a gas flow including approximately 400-600 standard cubic centimeters (sccm) hydrogen bromide (HBr) and approximately 1-8 sccm oxygen (O₂).

18. The method of claim 13, wherein after the first etching step the polysilicon layer has a substantially vertical profile.

19. A method of etching polysilicon in an etching chamber, the method comprising the steps of:
opening a capping layer over a polysilicon layer;
generating a substantially vertical profile in the polysilicon layer by:
first etching the polysilicon layer using a chemistry including a gas flow including perfluorocyclopentene (C₅F₈) and nitrogen trifluoride (NF₃); and
second etching to remove any polysilicon remainders.

20. The method of claim 13, wherein the first etching step includes using the perfluorocyclopentene (C₅F₈) and nitrogen trifluoride (NF₃) in a ratio of approximately 1:4.
